(19) United States
(12) Patent Application Publication
(10) Pub. No.: US 2024/0114758 A1
(43) Pub. Date: Apr. 4, 2024

(54) METAL MASK

(71) Applicant: DARWIN PRECISIONS CORPORATION, Hukou Township (TW)

(72) Inventors: Yun-Pei YANG, HUKOU TOWNSHIP (TW); Chi-Wei LIN, HUKOU TOWNSHIP (TW)

(21) Appl. No.: 17/987,195

(22) Filed: Nov. 15, 2022

(30) Foreign Application Priority Data
Sep. 21, 2022 (TW) 111135750

(51) Int. Cl. C23C 16/00; C23C 14/24

(52) U.S. Cl. CPC H01L 51/0011; C23C 14/24; H01L 51/001; H01L 51/56

(57) ABSTRACT

A metal mask has a first surface, a second surface opposite to the first surface, first and second openings provided on the first and second surfaces respectively, and first and second through holes communicating with the first and second openings respectively. The juncture of the first and second through holes further has an annular protrusion. The mask satisfies the in equations:

$$1 {μm}^{2} < \frac{1}{2} \times W \times H < 15 {μm}^{2} and 30 ° < θ < 65 ° ,$$

wherein W is the horizontal distance between an edge of the first opening and an imaginary connecting line passing through an edge of the second opening and an end edge of the annular protrusion, H is the vertical distance between the end edge of the annular protrusion and the first surface, and θ is the included angle between the imaginary connecting line and an imaginary extending plane of the first surface. The metal mask is effective in reducing shadow effect, thereby improving evaporation quality.

### BACKGROUND OF THE INVENTION

### 1. Field of the Invention

The present invention relates to masks and more particularly, to a metal mask for the evaporation process.

### 2. Description of the Related Art

In the manufacture of organic light emitting diode (OLED) panels, there is generally a mask having a plurality of evaporation holes and placed between an evaporation source and a substrate, so that in the evaporation process organic material particles pass through the evaporation holes and attach to the substrate, thereby forming an organic light emitting layer.

At present, the aforementioned mask is primarily manufactured in a double-sided etching manner. But because of a lateral erosion problem in the manufacturing process, the opening on one of the sides is formed on the periphery thereof with a breach. Such a breach will cause a part of the organic material particles to be covered by the inner wall of the evaporation hole, which means bringing the so-called shadow effect. If the shadow effect is too severe, the substrate will have the situation of color lacking, uneven or mixing. Therefore, the traditional mask will cause the substrate poor quality of evaporation.

### SUMMARY OF THE INVENTION

It is a primary objective of the present invention to provide a metal mask, which can effectively reduce the shadow effect, thereby improving the quality of evaporation.

To attain the above primary objective, the present invention provides a metal mask which includes a first surface, a first opening provided on the first surface, a second surface opposite to the first surface, and a second opening provided on the second surface. Besides, the metal mask further includes a first through hole communicating with the first opening, and a second through hole communicating with the second opening. The first through hole and the second through hole communicate with each other to become an evaporation hole. The metal mask further includes an annular protrusion located at the juncture of the first through hole and the second through hole. The annular protrusion, the first opening and the second opening satisfy the following in equations:

$$1 {μm}^{2} < \frac{1}{2} \times W \times H < 15 {μm}^{2} and 30 ° < θ < 65 ° ,$$

wherein W is the horizontal distance between an edge of the first opening and an imaginary connecting line, the imaginary connecting line passes through an edge of the second opening and an end edge of the annular protrusion, H is the vertical distance between the end edge of the annular protrusion and the first surface, and θ is the included angle between the imaginary connecting line and an imaginary extending plane of the first surface.

It can be known from the aforementioned in equations that the metal mask of the present invention under specific sizes can reduce the affection of the shadow effect to the lowest extent so as to attain the effect of improving the quality of evaporation, thereby quite suitable to be applied to the evaporation process requiring high precision, such as the manufacturing process of OLED panel.

Preferably, the caliber of the first opening is smaller than the caliber of the second opening.

Preferably, the cross-sectional shape of the first through hole and the cross-sectional shape of the second through hole are both semicircles.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a schematic planar view of a metal mask of the present invention.

FIG. 2 is a sectional view taken along the line 2-2 in FIG. 1.

FIG. 3 is a diagram showing the manufacturing process of the metal mask of the present invention.

### DETAILED DESCRIPTION OF THE INVENTION

First of all, it is to be mentioned that throughout this specification, including the following embodiment and claims, the directional terms are all based on the direction shown in the figures. Besides, same reference numerals used in the following embodiment and the appendix drawings designate same or similar elements or the structural features thereof.

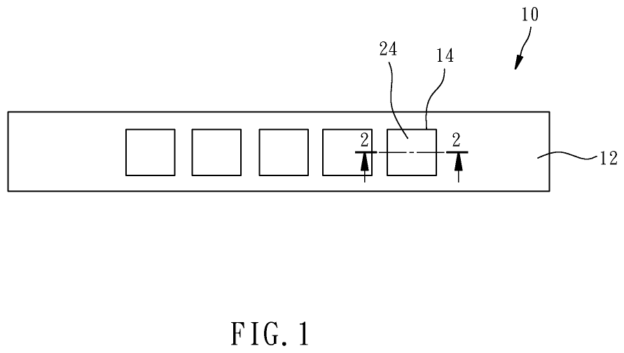

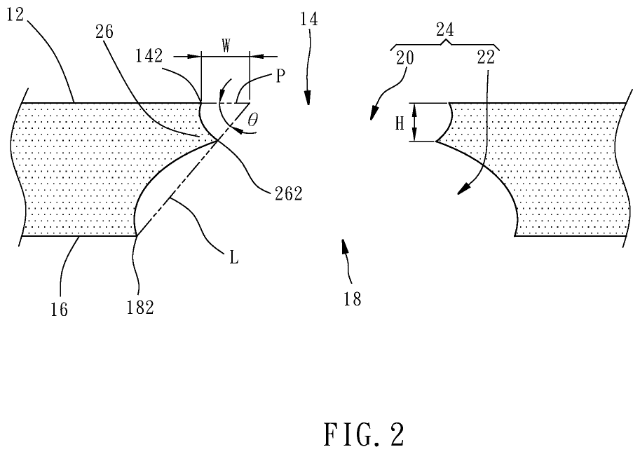

Referring to FIG. 1 and FIG. 2, a metal mask 10 of the present invention is made of nickel-iron alloy or stainless steel, which includes a first surface 12, a first opening 14 provided on the first surface 12, a second surface 16 opposite to the first surface 12, and a second opening 18 provided on the second surface 16. The caliber of the first opening 14 is smaller than the caliber of the second opening 18. Besides, the metal mask 10 of the present invention further includes a first through hole 20 communicating with the first opening 14 and a second through hole 22 communicating with the second opening 18. The cross-sectional shape of the first through hole 20 and the cross-sectional shape of the second through hole 22 are both semicircles, and the first through hole 20 and second through hole 22 communicate with each other to collectively form an evaporation hole 24. In addition, the metal mask 10 of the present invention further includes an annular protrusion 26 located at the juncture of the first through hole 20 and the second through hole 22. The annular protrusion 26, the first opening 14 and the second opening 18 satisfy the following in equations:

$$1 {μm}^{2} < \frac{1}{2} \times W \times H < 15 {μm}^{2} and 30 ° < θ < 65 ° ,$$

wherein W is the horizontal distance between an edge 142 of the first opening 14 and an imaginary connecting line L, the imaginary connecting line L passes through an edge 182 of the second opening 18 and an end edge 262 of the annular protrusion 26, H is the vertical distance between the end edge 262 of the annular protrusion 26 and the first surface 12, and 0 is the included angle between the imaginary connecting line L and an imaginary extending plane P of the first surface 12.

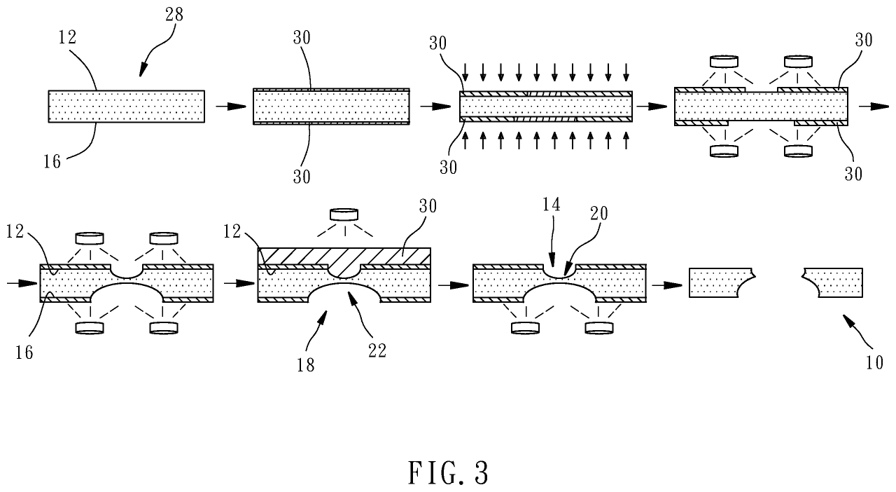

In another aspect, the metal mask 10 of the present invention is manufactured in a double-sided etching manner. Further speaking, as shown in FIG. 3, a pre-treatment is firstly performed to the first surface 12 and second surface 16 of a main body 28, and then the first surface 12 and the second surface 16 are each applied with a layer of photoresist 30. After that, exposure and developing are performed to the upper and lower layers of photoresist 30, and then the first time of etching is performed to the first surface 12 and the second surface 16 to obtain the second opening 18 and the second through hole 22. Then the first surface 12 is applied with another layer of photoresist 30, and then the second time of etching is performed from the second surface 16 to obtain the first opening 14 and the first through hole 20. At last, the upper and lower layers of photoresist 30 are removed so that the metal mask 10 of the present invention is obtained. In this embodiment, the above-described manufacturing process uses the etchant having a 40%-50% ferric chloride concentration, the spray pressure for the etchant is 0.1-0.3 Mpa, the moving speed of the main body 28 is 0.5-3 m/min, and the temperature of the manufacturing process is 35° C.-60° C.

It can be known from the above description that in the condition that the sizes of the metal mask 10 of the present invention satisfy the aforementioned in equations, the deviation between the actual position of the organic material particles after the evaporation and the position thereof predetermined before the evaporation can be controlled to be below ±3 μm, as shown in Table 1, such that the affection of the shadow effect can be reduced to the lowest extent and thereby the effect of improving the quality of evaporation is attained. It is quite suitable to be applied to the evaporation process requiring high precision, such as the manufacturing process of OLED panel.

TABLE 1

| Sample | H(μm) | W(μm) | $\frac{1}{2} \times W \times H$ | θ | shadow effect < ±3 μm |
|---|---|---|---|---|---|
| 1 | 6.0 | 10.9 | 32.7 | 29.5 | X |
| 2 | 6.0 | 3.8 | 11.4 | 64.0 | O |
| 3 | 5.1 | 6.0 | 15.2 | 44.0 | X |
| 4 | 5.0 | 3.5 | 8.9 | 63.8 | O |
| 5 | 3.8 | 8.1 | 15.4 | 28.8 | X |
| 6 | 4.1 | 4.3 | 8.8 | 49.0 | O |
| 7 | 3.0 | 2.2 | 3.3 | 68.9 | X |
| 8 | 3.1 | 3.3 | 5.1 | 49.2 | O |
| 9 | 2.3 | 2.0 | 2.3 | 68.77 | X |
| 10 | 1.9 | 2.1 | 2.0 | 59.02 | O |

What is claimed is:

1. A metal mask, the metal mask comprising a first surface, a first opening provided on the first surface, a second surface opposite to the first surface, and a second opening provided on the second surface, the metal mask further comprising a first through hole communicating with the first opening and a second through hole communicating with the second opening, the first through hole and the second through hole communicating with each other to become an evaporation hole, the metal mask further comprising an annular protrusion located at a juncture of the first through hole and the second through hole, the annular protrusion, the first opening and the second opening satisfying following in equations:
$$1 {μm}^{2} < \frac{1}{2} \times W \times H < 15 {μm}^{2} and 30 ° < θ < 65 ° ,$$
wherein W is a horizontal distance between an edge of the first opening and an imaginary connecting line, the imaginary connecting line passes through an edge of the second opening and an end edge of the annular protrusion, H is a vertical distance between the end edge of the annular protrusion and the first surface, and θ is an included angle between the imaginary connecting line and an imaginary extending plane of the first surface.

2. The metal mask as claimed in claim 1, wherein a caliber of the first opening is smaller than a caliber of the second opening.

3. The metal mask as claimed in claim 2, wherein a cross-sectional shape of the first through hole and a cross-sectional shape of the second through hole are both semicircles.

4. The metal mask as claimed in claim 1, wherein a cross-sectional shape of the first through hole and a cross-sectional shape of the second through hole are both semicircles.
